(19) United States
(12) Patent Application Publication
(10) Pub. No.: US 2016/0037679 A1
(43) Pub. Date: Feb. 4, 2016

(54) High efficiency radiator and manufacturing method thereof

(71) Applicant: Guangdong Thermal Management Technology Co., Limited, Hongkong (CN)

(72) Inventor: Weizeng Deng, Hongkong (CN)

(73) Assignee: Guangdong Thermal Management Technology Co., Limited

(21) Appl. No.: 14/486,060

(22) Filed: Sep. 15, 2014

(30) Foreign Application Priority Data
Jul. 30, 2014 (CN) 201410368240.7

(51) Int. Cl. H05K 7/20

(52) U.S. Cl. CPC H05K 7/20254; H05K 7/20263

(57) ABSTRACT

A high efficiency radiator and a manufacturing method thereof are disclosed. The high efficiency radiator includes: a radiating set, a closed ring and a basement membrane. The basement membrane has a chamber, the radiating set is provided in the chamber of the basement. The closed ring is provided on a connecting gap between the radiating set and the basement membrane. The radiating set comprises a cover plate and a plurality of radiating fins. The radiating fins are provided on a surface of the cover plate at an equal interval. The radiating fins are provided in the chamber of the basement membrane, and the cover plate is provided on an opening of the basement membrane and connected with the closed ring. The present invention has advantages of high radiation efficiency, light weight, low cost and wide application.

### CROSS REFERENCE OF RELATED APPLICATION

The present application claims priority under 35 U.S.C. 119(a-d) to CN 201410368240.7, filed Jul. 30, 2014.

### BACKGROUND OF THE PRESENT INVENTION

1. Field of Invention

The present invention relates to the field of heat dissipation in thermology, and more particularly to a high efficiency radiator and a manufacturing method thereof.

2. Description of Related Arts

With the improvement of living standards, people's demand on the performances of electronic products becomes increasingly higher. As an essential element to improve performances of products, radiating treatment has been widely developed.

The conventional radiating methods comprise the following types of:

1. air cooling;

2. liquid cooling;

3. heat pipe;

4. vapor chamber technology;

5. dual piezoelectric cooling jets;

6. Sandia cooler (air bearing heat exchanger);

7. semiconductor refrigeration, which has advantages of low cooling temperature, high reliability and etc., wherein the temperature of the cold surface is capable of reaching minus 10° C.; however, the cost is too high, and dew condensation of CPU caused by over low temperature may lead to a short circuit; further, since the technique of semiconductor refrigeration plate is immature, the semiconductor refrigeration is not practical enough;

8. chemical refrigeration, which is common in laboratories or extreme overclocking enthusiasts.

However, no matter which radiating method is adopted, the problem that how to quickly transfer heat from a heat source, such as CPU, to a radiating body in a high efficiency must be firstly solved. For example, if air cooling is adopted for radiating, heat generated by CPU needs to be transferred to a radiating plate by thermal conductivity, and then most of the heat is taken away via high speed rotation of a fan by convection comprising forced convection and natural convection, which applies to the liquid cooling for radiating as well. During the process mentioned above, heat directly radiated by the radiating mode is very little, which on the other hand indicates that thermal radiation rate of liquid adopted by the radiator in the liquid cooling is very low. The radiator in the liquid cooling achieves heat radiation mainly by physical phase transition of the liquid.

Furthermore, the manner of fixing or containing the liquid for radiating is by a metal hole or a chamber, rather than enhancing radiation by electrostatic field. The determining factor is the first step of improving heat conduction efficiency to take away the heat from the heat source.

The patent applications, CN201110131537.8, CN200710124770.7 and US20070058357, all disclosed embodiments of products for performing heat radiation, whose specific technical solutions are as follows.

The Chinese patent application with the application number of CN201110131537.8 disclosed a radiating unit and a manufacturing method thereof. The radiating unit comprises a chamber, an oxide film and a metal body for working fluid, wherein the oxide film is provided outside the metal body, and the working fluid flows in the chamber. However, radiating structures in the technical solution is so simple that the radiation effect is seriously affected. In addition, the oxide film is a hydrophobic or hydrophilic film and has a low thermal transmittance rate, which further reduces the radiating effect.

The Chinese patent application having the application number of CN200710124770.7 disclosed an assembling method of a heat pipe and a radiating device matched therewith, comprising steps of: covering a surface of the heat pipe with a solid solder film; inserting the heat pipe covering with the solid solder film into a radiating set having openings, heating the heat pipe and the radiating set; and cooling to form the radiating device desired. Since the solder film is filled between the radiating set and the heat pipe after being heated and melted, which result in the incomplete solder films, the radiating effects are affected. In addition, the assembling technique of the radiating device is complicated and expensive.

The U.S. patent application having the application number of US20070058357 disclosed a radiating device for an LED lamp, which has a simple structure to affect the radiating effect. In addition, the oxide film is a hydrophobic or hydrophilic film and has a low thermal transmittance rate, which further reduces the radiating effect.

### SUMMARY OF THE PRESENT INVENTION

Accordingly, in order to solve the problems existing in the conventional radiating devices such as poor radiating effect, complicated manufacturing method and high manufacturing cost, the present invention provides a high efficiency radiator and a manufacturing method thereof. A specific technical solution of the present invention is as follows.

The present invention provides a high efficiency radiator, comprising: a radiating set, a closed ring and a basement membrane;

wherein the basement membrane has a chamber, the radiating set is provided in the chamber of the basement membrane, the closed ring is provided in a connecting gap between the radiating set and the basement membrane; and

wherein the radiating set comprises a cover plate and a plurality of radiating fins, the plurality of radiating fins are provided on a surface of the cover plate at an equal interval, the plurality of radiating fins are provided in the chamber of the basement membrane, and the cover plate is provided on an opening of the basement membrane and connected with the closed ring.

Preferably, the high efficiency radiator further comprises a metal electrode, wherein the metal electrode is provided on the radiating set and insulated from the radiating set, an electrode tip of the metal electrode is connected with an RC absorbing circuit of an external switching power supply.

Preferably, the basement membrane has a liquid inlet, and a liquid plug coupling with the liquid inlet is provided on the basement membrane; radiating liquid is injected into a sealed container formed by the basement membrane and the radiating set via the liquid inlet, and the liquid plug is for covering the liquid inlet.

Preferably, the radiating liquid is water or oil.

Preferably, the closed ring is mounted on the basement membrane by buckling or screwing.

Preferably, the basement membrane is a tear tape or an electrical insulating membrane.

Preferably, the radiating set is made of aluminum or copper.

The present invention further provides a method for manufacturing the high efficiency radiator as mentioned above, comprising steps of:

forming the basement membrane into a preset shape having a chamber;

installing the metal electrode on the radiating set, wherein the metal electrode is insulated from the radiating set, and the electrode tip of the metal electrode extends out of the radiating set; and

providing the closed ring on the connecting gap between the radiating set and the basement membrane, in such a manner that the radiating set and the basement membrane form a sealed container via the closed ring.

Preferably, the method further comprises steps of:

injecting the radiating liquid into the sealed container formed by the basement membrane and the radiating set via the liquid inlet of the basement membrane; and covering the liquid plug on the liquid inlet.

Preferably, the method further comprises step of: connecting the metal electrode to the RC absorbing circuit of the external switching power supply.

Compared with the conventional art, the high efficiency radiator and the manufacturing method of the present invention have beneficial effects as follows. In the present invention, the basement membrane having a high thermal transmittance rate is formed on the radiating set. The chamber of the basement membrane is utilized for containing the radiating liquid. Thus, the high efficiency radiator of the present invention not only has an excellent effect, but also has advantages of light weight and low cost. In addition, in the present invention, the metal electrode is connected with the RC absorbing circuit of the external switching power supply, and the electrostatic field is utilized to intensify radiation, which further improves the radiating effect.

In conclusion, the high efficiency radiator provided by the present invention is capable of being applied in various conditions for temperature controlling, and has advantages of great expansibility and wide application.

### BRIEF DESCRIPTION OF THE DRAWINGS

FIG. 1 is an exploded view of a high efficiency radiator according to Embodiment 1 of the present invention.

FIG. 2 is a side sketch view of the high efficiency radiator according to the Embodiment 1 of the present invention.

FIG. 3 is a top view of the efficiency radiator according to the Embodiment 1 of the present invention.

FIG. 4 is a bottom view of the efficiency radiator according to the Embodiment 1 of the present invention.

FIG. 5 is a perspective view of a radiating set of the high efficiency radiator according to the Embodiment 1 of the present invention.

### DETAILED DESCRIPTION OF THE PREFERRED EMBODIMENT

These and other objectives, features, and advantages of the present invention will become apparent from the following detailed description, the accompanying drawings, and the appended claims. One skilled in the art will understand that the embodiment of the present invention as shown in the drawings and described above is exemplary only and not intended to be limiting.

### Embodiment 1

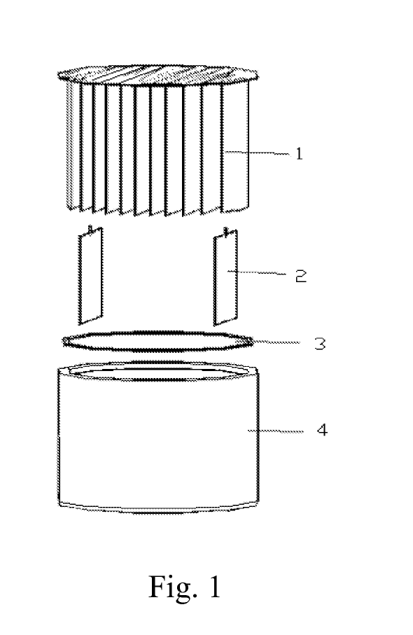

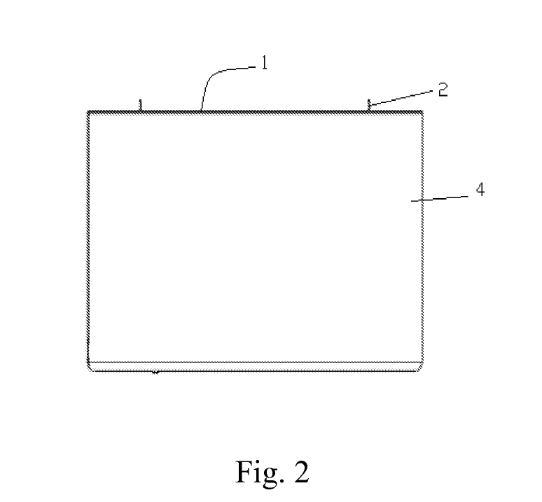

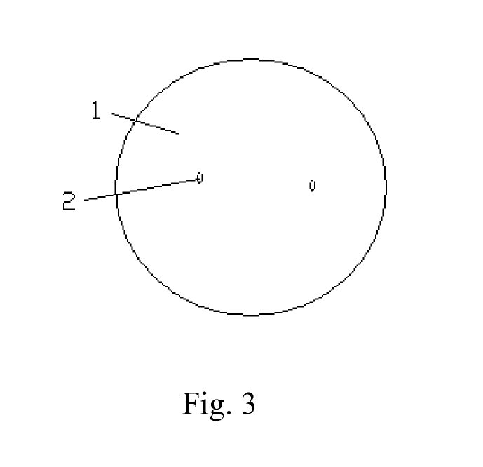

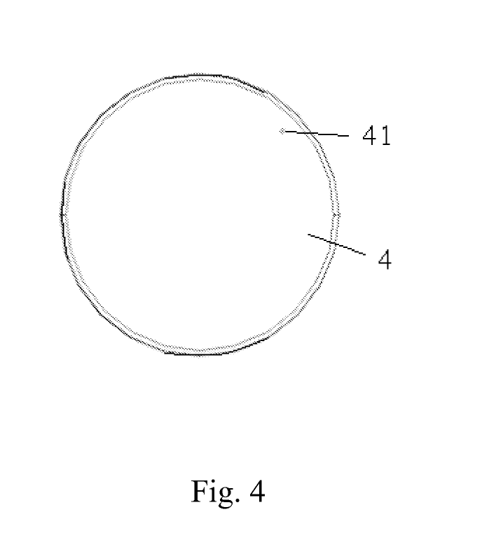

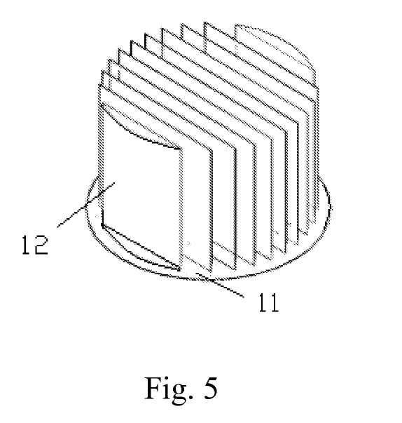

Referring to FIGS. 1-5, the present invention provides a high efficiency radiator comprises: a radiating set 1, a metal electrode 2, a closed ring 3 and a basement membrane 4. The basement membrane 4 has an opening (not shown in the Figs.) provided on a first side and a bottom provided on a second side (not shown in the Figs.). The basement membrane 4 has a chamber (not shown in the Figs.). According to the requirements of actual operation, the basement membrane 4 is capable of forming different shapes to match the radiating set 1, such as a cylindrical shape. The basement membrane 4 is a tear tape which has advantages of high thermal transmittance rate, high tensile strength and great toughness. The basement membrane 4 may adopt an electrical insulating membrane.

The radiating set 1 comprises a cover plate 11 and a plurality of radiating fins 12, wherein the plurality of radiating fins are provided on a surface of the cover plate 11 at an equal interval. The radiating set 1 is provided in the chamber of the basement membrane 4, i.e. the radiating fins of the radiating set are provided in the chamber of the basement membrane 4. The cover plate 11 is provided on the opening of the basement membrane 4 and connected with the closed ring 3. The radiating set 1 is made of aluminum or other types of metal with high thermal conductivity according to the requirements of actual operation, such as copper.

A number of the metal electrode 2 is two. An electrode tip (not shown in the Figs.) is respectively provided on a top of each metal electrode. The metal electrode 2 is installed on the radiating set 1 and insulated from the radiating set 1. Furthermore, the electrode tip of the metal electrode 2 passes through the cover plate 11 of the radiating set 1 and extends out of the radiating set 1. The metal electrode 2 is connected with an RC absorbing circuit of an external switching power supply. If an electrostatic field is required to intensify radiation, the metal electrode 2 is connected with the RC absorbing circuit of the external switching power supply for heat radiation.

The closed ring 3 is provided on a connecting gap between the radiating set 1 and the basement membrane 4, i.e., the radiating set 1 and the basement membrane 4 form a sealed container via the closed ring 3. The closed ring 3 is mounted on the basement membrane 4 by buckling or screwing.

The basement membrane 4 has a liquid inlet (not shown in the Figs.), and a liquid plug 41 coupling with the liquid inlet is provided on the basement membrane 4. Radiating liquid is injected into the sealed container formed by the basement membrane 4 and the radiating set 1 via the liquid inlet. The liquid plug 41 is for covering the liquid inlet. The radiating liquid is water or oil.

### Embodiment 2

Further referring to FIGS. 1-5, the present invention provides a method for manufacturing the high efficiency radiator as recited in the Embodiment 1, comprising steps of:

forming the basement membrane into a preset shape having a chamber, wherein the basement membrane can be formed into different shapes to match with the radiating set 1 , such as a cylindrical shape, wherein the basement membrane is a tear tape which has advantages of high thermal transmittance rate, high tensile strength and great toughness;

installing the metal electrode 2 on the radiating set 1, wherein the metal electrode 2 is insulated from the radiating set 1, and the electrode tip of the metal electrode 2 extends out of the radiating set 1, i.e., the electrode tip of the metal electrode 2 passes through the cover plate 11 of the radiating set 1 and extends out of the radiating set 1;

providing the closed ring 3 on the connecting gap between the radiating set 1 and the basement membrane 4, in such a manner that the radiating set 1 and the basement membrane 4 form a sealed container via the closed ring 3, wherein the closed ring 3 is mounted on the basement membrane 4 by buckling or screwing; and

injecting the radiating liquid into the sealed container formed by the basement membrane 4 and the radiating set 1 via the liquid inlet of the basement membrane;

covering the liquid plug 41 on the liquid inlet, wherein the radiating liquid is water; and

connecting the metal electrode 2 to the RC absorbing circuit of the external switching power supply; wherein if an electrostatic field is required to intensify radiation, the metal electrode 2 is connected with the RC absorbing circuit of the external switching power supply for heat radiation.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A high efficiency radiator, comprising: a radiating set, a closed ring and a basement membrane;
wherein the basement membrane has a chamber, the radiating set is provided in the chamber of the basement membrane, the closed ring is provided in a connecting gap between the radiating set and the basement membrane; and
wherein the radiating set comprises a cover plate and a plurality of radiating fins, the plurality of radiating fins are provided on a surface of the cover plate at an equal interval, the plurality of radiating fins are provided in the chamber of the basement membrane, and the cover plate is provided on an opening of the basement membrane and connected with the closed ring.

2. The high efficiency radiator, as recited in claim 1, further comprising a metal electrode, wherein the metal electrode is provided on the radiating set and insulated from the radiating set, an electrode tip of the metal electrode is connected with an RC absorbing circuit of an external switching power supply.

3. The high efficiency radiator, as recited in claim 2, wherein the basement membrane has a liquid inlet, and a liquid plug coupling with the liquid inlet is provided on the basement membrane; radiating liquid is injected into a sealed container formed by the basement membrane and the radiating set via the liquid inlet, and the liquid plug is for covering the liquid inlet.

4. The high efficiency radiator, as recited in claim 3, wherein the radiating liquid is water or oil.

5. The high efficiency radiator, as recited in claim 1, wherein the closed ring is mounted on the basement membrane by buckling or screwing.

6. The high efficiency radiator, as recited in claim 1, wherein the basement membrane is a tear tape or an electrical insulating membrane.

7. The high efficiency radiator, as recited in claim 1, wherein the radiating set is made of aluminum or copper.

8. A method for manufacturing the high efficiency radiator as recited in any of the claims 1, comprising steps of:
forming the basement membrane into a preset shape having a chamber;
installing the metal electrode on the radiating set, wherein the metal electrode is insulated from the radiating set, and the electrode tip of the metal electrode extends out of the radiating set; and
providing the closed ring on the connecting gap between the radiating set and the basement membrane, in such a manner that the radiating set and the basement membrane form a sealed container via the closed ring.

9. The method for manufacturing the high efficiency radiator, as recited in claim 8, further comprising steps of:
injecting the radiating liquid into the sealed container formed by the basement membrane and the radiating set via the liquid inlet of the basement membrane; and
covering the liquid plug on the liquid inlet, wherein the radiating liquid is water.

10. The method for manufacturing the high efficiency radiator, as recited in claim 9, further comprising a step of:
connecting the metal electrode to the RC absorbing circuit of the external switching power supply.
